(19) United States
(12) Patent Application Publication
(10) Pub. No.: US 2025/0107449 A1
(43) Pub. Date: Mar. 27, 2025

(54) PIEZOELECTRIC ELEMENT AND ACTUATOR

(71) Applicant: FUJIFILM CORPORATION, Tokyo (JP)

(72) Inventors: Tsutomu SASAKI, Kanagawa (JP); SEIGO NAKAMURA, Kanagawa (JP)

(21) Appl. No.: 18/889,387

(22) Filed: Sep. 19, 2024

(30) Foreign Application Priority Data
Sep. 27, 2023 (JP) 2023-166050

(51) Int. Cl. H10N 30/00; H10N 30/20; H10N 30/50; H10N 30/80; H10N 30/853; H10N 30/87

(52) U.S. Cl. CPC H10N 30/704; H10N 30/206; H10N 30/50; H10N 30/802; H10N 30/8554; H10N 30/871; H10N 30/877

(57) ABSTRACT

In a piezoelectric element and an actuator, the piezoelectric element includes a substrate; and a first electrode, a first piezoelectric film, a second electrode, a second piezoelectric film, and a third electrode provided on the substrate in this order, in which the first piezoelectric film and the second piezoelectric film each have a perovskite-type oxide as a main component, and one of the first piezoelectric film and the second piezoelectric film is an epitaxial film and the other is a uniaxial alignment film.

### CROSS REFERENCE TO RELATED APPLICATIONS

This application claims priority from Japanese Application No. 2023-166050, filed on Sep. 27, 2023, the entire disclosure of which is incorporated herein by reference.

### BACKGROUND

### 1. Technical Field

The present disclosure relates to a piezoelectric element and an actuator.

### 2. Related Art

As a material having excellent piezoelectric characteristics and excellent ferroelectricity, there is known a perovskite-type oxide such as lead zirconate titanate (Pb(Zr,Ti)O₃, hereinafter referred to as PZT). A piezoelectric body consisting of a perovskite-type oxide is applied as a piezoelectric film in a piezoelectric element comprising a lower electrode, a piezoelectric film, and an upper electrode on a substrate. This piezoelectric element has been developed into various devices such as a memory, an inkjet head (an actuator), a micromirror device, an angular velocity sensor, a gyro sensor, a piezoelectric micromachined ultrasonic transducer (PMUT), and an oscillation power generation device.

As the piezoelectric element, in order to obtain high piezoelectric characteristics, a laminated piezoelectric element in which a plurality of piezoelectric films are laminated via an electrode has been proposed (JP1999-233844A (JP-H11-233844A), WO2017/018222A, and the like).

JP1999-233844A (JP-H11-233844A) discloses a piezoelectric element in which a plurality of layers of PZT films uniaxially aligned are laminated via an electrode. WO2017/018222A discloses a piezoelectric element in which a plurality of layers of (PbₐLa_{b})(Zr_{c}Ti_{d}Nbₑ)O_{3-δ} epitaxial films are laminated via an electrode. In any case, it is disclosed that a positive terminal and a negative terminal of a plurality of electrodes are connected every other layer, and a direction of an electric field applied to piezoelectric films laminated in a plurality of layers is alternately reversed.

### SUMMARY

As in JP1999-233844A (JP-H11-233844A) and WO2017/018222A, a piezoelectric element including a plurality layers of piezoelectric films can obtain a larger driving force as compared with a piezoelectric element including a single layer of a piezoelectric film.

However, the piezoelectric elements described in JP1999-233844A (JP-H11-233844A) and WO2017/018222A have the following problems. In a laminated piezoelectric element in which a plurality of layers of uniaxially aligned PZT films are laminated, since an electric field opposite to self-poling is applied to at least a part of a plurality of layers of piezoelectric films, a non-linear response component is generated so that linearity is low, and a displacement behavior assumed as a device cannot be realized. The laminated piezoelectric element in which piezoelectric films consisting of epitaxial films are laminated may have low long-term reliability.

The present disclosure has been made in view of the above circumstances, and an object of the present disclosure is to provide a piezoelectric element and a piezoelectric actuator capable of obtaining a large driving force, having good responsiveness, and obtaining long-term reliability at a low cost.

A piezoelectric element of the present disclosure comprises a substrate; and a first electrode, a first piezoelectric film, a second electrode, a second piezoelectric film, and a third electrode provided on the substrate in this order, in which the first piezoelectric film and the second piezoelectric film each have a perovskite-type oxide as a main component, and one of the first piezoelectric film and the second piezoelectric film is an epitaxial film and the other is a uniaxial alignment film.

It is preferable that the first piezoelectric film is an epitaxial film and the second piezoelectric film is a uniaxial alignment film.

It is preferable that a surface of the first electrode in contact with the first piezoelectric film is an epitaxial film.

It is preferable that the perovskite-type oxide which is a main component of the first piezoelectric film and the perovskite-type oxide which is a main component of the second piezoelectric film consist of the same constituent elements.

It is preferable that the perovskite-type oxide is lead zirconate titanate or lead zirconate titanate to which a metal element M is added, and the metal element M is at least one of vanadium, niobium, tantalum, antimony, molybdenum, or tungsten.

It is preferable that the metal element M in the perovskite-type oxide is niobium, and in a composition ratio of the perovskite-type oxide included in each of the first piezoelectric film and the second piezoelectric film, an addition amount of at least the metal element M is the same.

It is preferable that the first electrode, the second electrode, and the third electrode each contain at least one of iridium, platinum, strontium ruthenate, barium ruthenate, zirconium oxide, hafnium oxide, ruthenium, ruthenium oxide, iridium oxide, platinum oxide, or rhenium oxide.

The first electrode and the third electrode may be maintained at a ground potential, and the second electrode may be a drive electrode for applying a positive driving voltage to the first piezoelectric film and the second piezoelectric film.

The second electrode may be maintained at a ground potential, and the first electrode and the third electrode may be drive electrodes for applying a negative driving voltage to the first piezoelectric film and the second piezoelectric film.

An actuator of the present disclosure comprises the piezoelectric element of the present disclosure; and a drive circuit that applies a driving voltage to the piezoelectric element, in which the drive circuit applies, to the piezoelectric film which is the uniaxial alignment film, an electric field having the same direction as a direction of self-poling which is polarization that the piezoelectric film spontaneously has immediately after film formation, and applies, to the piezoelectric film which is the epitaxial film, an electric field having a direction opposite to the electric field applied to the piezoelectric film which is the uniaxial alignment film.

According to the technique of the present disclosure, it is possible to provide a piezoelectric element and a piezoelectric actuator capable of obtaining a large driving force, having good responsiveness, and obtaining long-term reliability at a low cost.

### BRIEF DESCRIPTION OF THE DRAWINGS

FIG. 1 is a cross-sectional view of a piezoelectric element according to one embodiment.

FIG. 2 is a diagram showing a schematic configuration of an actuator.

FIG. 3 is a diagram showing a schematic configuration of an actuator.

FIG. 4 is measurement data of a PZT epitaxial film by XRD-φ scanning.

FIG. 5 is a diagram showing a drive signal and a velocity waveform for a piezoelectric element of Example 1.

FIG. 6 is a diagram showing a drive signal and a velocity waveform for a piezoelectric element of Comparative Example 1.

### DESCRIPTION OF EMBODIMENTS

Hereinafter, an embodiment according to the present disclosure will be described with reference to the drawings. In the drawings below, a layer thickness of each of layers and a ratio thereof are appropriately changed and drawn for easy visibility, and thus they do not necessarily reflect the actual layer thickness and ratio.

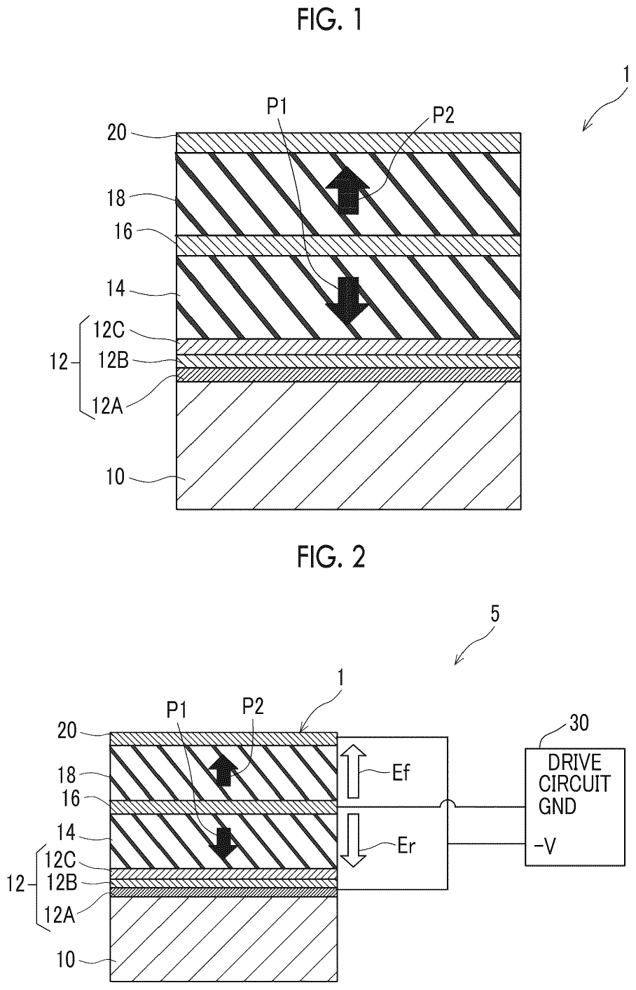

FIG. 1 is a cross-sectional schematic view showing a layer configuration of a piezoelectric element 1 according to one embodiment. As shown in FIG. 1, the piezoelectric element 1 comprises a first electrode 12, a first piezoelectric film 14, a second electrode 16, a second piezoelectric film 18, and a third electrode 20 on a substrate 10 in this order.

The substrate 10 is not particularly limited, and examples thereof include silicon, glass, stainless steel, yttrium-stabilized zirconia, alumina, sapphire, silicon carbide, or other substrates. As the substrate 10, a substrate consisting of single crystal silicon is particularly preferable.

The first electrode 12 and the second electrode 16 are paired with each other to apply a voltage to the first piezoelectric film 14. In addition, the second electrode 16 and the third electrode 20 are paired with each other to apply a voltage to the second piezoelectric film 18.

The main components of the first electrode 12, the second electrode 16, and the third electrode 20 are not particularly limited, and it is preferable that each of them includes at least one of iridium (Ir), platinum (Pt), strontium ruthenate (SrRuO₃), barium ruthenate (BaRuO₃), zirconium oxide (ZrO₂), hafnium oxide (HfO₂), ruthenium (Ru), ruthenium oxide (RuOₓ), iridium oxide (IrOₓ), platinum oxide (PtOₓ), or rhenium oxide (ReOₓ). Each of the first electrode 12, the second electrode 16, and the third electrode 20 may have a monolayer structure or may have a laminated structure of a plurality of layers.

The thicknesses of the first electrode 12, the second electrode 16, and the third electrode 20 are not particularly limited and are preferably about 50 nm to 300 nm, and more preferably 100 nm to 300 nm.

The first piezoelectric film 14 and the second piezoelectric film 18 each have a perovskite-type oxide represented by General Formula ABO₃ as a main component. In the present specification, the main component refers to a component occupying 80 mol % or more. It is preferable that 90 mol % or more of each of the first piezoelectric film 14 and the second piezoelectric film 18 is occupied by the perovskite-type oxide, and it is more preferable that the first piezoelectric film 14 and the second piezoelectric film 18 are composed of the perovskite-type oxide (however, containing unavoidable impurities). The perovskite-type oxide which is a main component of the first piezoelectric film 14 and the perovskite-type oxide which is a main component of the second piezoelectric film 18 may be composed of different constituent elements, or may have the same constituent elements. However, from the viewpoint of cost reduction, it is preferable that the perovskite-type oxides of the first piezoelectric film 14 and the second piezoelectric film 18 have the same constituent elements. The expression “have the same constituent elements” means that the elements contained are the same, but composition ratios thereof may be different.

The first piezoelectric film 14 and the second piezoelectric film 18 are preferably a so-called PZT-based perovskite-type oxide containing lead (Pb) at an A site and zirconium (Zr) and titanium (Ti) at a B site, and particularly preferably M-added PZT in which a metal element M is added to the B site. Here, the metal element M is at least one of vanadium (V), niobium (Nb), tantalum (Ta), antimony (Sb), molybdenum (Mo), or tungsten (W). The M-added PZT is represented by the following general formula.

Pbₐ{(ZrₓTi₁₋ₓ)_{1-y}M_{y}}O₃

Here, 0<x<1, 0<y<1, and 0.9≤a≤1.2 are satisfied. A reference molar ratio a of Pb is 1, but in a range of 0.9≤a≤1.2, a perovskite-type structure can be obtained.

The metal element M may be a single element such as V only or Nb only, or it may be a combination of two or three or more elements, such as a mixture of V and Nb or a mixture of V, Nb, and Ta. In a case where the metal element M is these elements, a very high piezoelectric constant can be realized in combination with Pb of the A site element.

In particular, Pbₐ{(ZrₓTi₁₋ₓ)_{1-y}Nb_{y}}O₃ in which the metal element M is Nb is optimal. In this case, in a case where 0.1≤y≤0.3, a higher piezoelectric constant can be obtained.

It is preferable that both the first piezoelectric film 14 and the second piezoelectric film 18 contain Nb-added PZT as a main component. In this case, it is preferable that Nb composition ratios of the Nb-added PZT which is a main component of the first piezoelectric film 14 and the Nb-added PZT which is a main component of the second piezoelectric film 18 are the same. That is, in a case where, in the first piezoelectric film 14, a Pb composition ratio is denoted by a1, a Zr composition ratio is denoted by x1, and an M composition ratio is denoted by y1, and in the perovskite-type oxide in the second piezoelectric film 18, a Pb composition ratio is denoted by a2, a Zr composition ratio is denoted by x2, and an M composition ratio is denoted by y2, it is preferable that y1=y2. It is more preferable that x1 and x2 are the same in addition to y1=y2. Here, the fact that the composition ratios are the same means that the composition ratios are equal within a range of a measurement error. As a method for measuring the composition, there are a plurality of analysis methods such as inductively coupled plasma (ICP) emission spectroscopy or X-ray fluorescence (XRF). For example, in a case where composition analysis is performed by XRF, a measurement error is about 0.005.

It is said that, in the PZT-based perovskite-type oxide, high piezoelectric characteristics are exhibited at a morphotropic phase boundary (MPB) and its vicinity. Zr: Ti (molar ratio) of around 52/48 is an MPB composition, and in the above general formula, the MPB composition or its vicinity is preferable. The “MPB or its vicinity” refers to a region in which a phase transition occurs in a case where an electric field is applied to the piezoelectric film. Specifically, Zr: Ti (molar ratio) is preferably in a range of 45:55 to 55:45, that is, in a range of x=0.45 to 0.55.

A film thickness t1 of the first piezoelectric film 14 and a film thickness t2 of the second piezoelectric film 18 are preferably 0.1 μm or more and 5 μm or less, and more preferably 1 μm or more and less than 5 μm. The film thicknesses of the first piezoelectric film 14 and the second piezoelectric film 18 may be the same as or different from each other. The first piezoelectric film 14 and the second piezoelectric film 18 are preferably 2 μm or less in thickness.

One of the first piezoelectric film 14 and the second piezoelectric film 18 is an epitaxial film, and the other thereof is a uniaxial alignment film. In particular, it is preferable that the first piezoelectric film 14 disposed on the substrate 10 side is an epitaxial film and the second piezoelectric film 18 is a uniaxial alignment film. Hereinafter, a case where the first piezoelectric film 14 is an epitaxial film and the second piezoelectric film 18 is a uniaxial alignment film will be described.

In order to epitaxially grow the first piezoelectric film 14, it is particularly preferable to use a single crystal silicon substrate as the substrate 10, and to provide, as the first electrode 12, a laminated structure of a first film 12A consisting of a ZrO₂ or HfO₂ film, a second film 12B consisting of a Pt film or an Ir film, and a third film 12C consisting of a SrRuO₃ or BaRuO₃ film, on the single crystal silicon substrate. In order to epitaxially grow the first piezoelectric film 14, it is preferable that a surface of the first electrode 12 in contact with the first piezoelectric film 14 is an epitaxial film. That is, in a case where the first electrode 12 has a three-layer structure as described above, it is preferable that the third film 12C, which is closest to the first piezoelectric film 14, is an epitaxial film.

In the second piezoelectric film 18 which is a uniaxial alignment film, spontaneous polarization is aligned upward in a film thickness direction in a state in which an external electric field is not applied. An arrow P2 in FIG. 1 indicates a direction of polarization. Hereinafter, the direction of the polarization is referred to as a direction P2. Whether or not the spontaneous polarization in the piezoelectric film is aligned and the direction in which the spontaneous polarization is aligned can be confirmed by measuring a P-V hysteresis curve (or P-E hysteresis curve) showing polarization-voltage characteristics (or polarization-electric field characteristics) of the piezoelectric film.

The fact that the second piezoelectric film 18 is a uniaxial alignment film means that the perovskite-type oxide, which is a main component of the second piezoelectric film 18, is uniaxially aligned. The perovskite-type oxide that is uniaxially aligned is a film which is spontaneously polarized in a state immediately after film formation without being subjected to a poling treatment, that is, in which the direction of the spontaneous polarization is aligned and which is polarized in the film thickness direction. In the piezoelectric film that has not been subjected to the poling treatment, the reason why the direction of the spontaneous polarization is aligned in a state in which an external electric field is not applied is thought to be due to the generation of an electric field caused by distortion or defect of a crystal structure (hereinafter referred to as a spontaneous internal electric field) in the piezoelectric film. The second piezoelectric film 18 has spontaneous polarization aligned in the film thickness direction due to such a spontaneous internal electric field. The second piezoelectric film 18 is a piezoelectric film that is polarized in the film thickness direction in a state in which spontaneous polarization is aligned in the film thickness direction without application of an external electric field. The piezoelectric film is composed of a large number of domains that are spontaneously polarized. In the present specification, the expression “the spontaneous polarization is aligned in a specific direction” means a state in which spontaneous polarization components in a specific direction are relatively larger than spontaneous polarization components in other directions. In a case where the spontaneous polarization components in a specific direction are relatively larger than the spontaneous polarization components in other directions in the piezoelectric film, the piezoelectric film is regarded as a film polarized in the specific direction.

Meanwhile, the first piezoelectric film 14 is an epitaxial film, and the spontaneous polarization thereof is isotropic in a state in which no poling treatment is performed. Therefore, the first piezoelectric film 14 is polarized in a direction in which an electric field is applied, and a stable polarization state is obtained.

FIG. 2 shows a schematic configuration of an actuator 5 comprising the piezoelectric element 1. The actuator 5 includes the piezoelectric element 1 and a drive circuit 30.

The drive circuit 30 is means for supplying a driving voltage to the first piezoelectric film 14 and the second piezoelectric film 18 interposed between the electrodes in order to drive the piezoelectric element 1. In the present example, the second electrode 16 is connected to a ground terminal (GND) of the drive circuit 30, and the first electrode 12 and the third electrode 20 are connected to a driving voltage output terminal (−V) of the drive circuit 30. As a result, the drive circuit 30 applies electric fields to the first piezoelectric film 14 and the second piezoelectric film 18 in opposite directions to each other. In the present example, the drive circuit 30 applies an electric field Ef having the same direction as the direction P2 in which the spontaneous polarization is aligned (direction of the polarization) to the second piezoelectric film 18 which is one piezoelectric film, and applies an electric field Er having an opposite direction to the electric field Ef applied to the second piezoelectric film 18 to the first piezoelectric film 14 which is the other piezoelectric film. The drive circuit 30 is a negative drive circuit that applies a negative potential to a drive electrode (here, the second electrode 16). In the actuator 5 shown in FIG. 2, in the piezoelectric element 1, the second electrode 16 is set to a ground potential, and the first electrode 12 and the third electrode 20 are used as drive electrodes. In the present example, in the piezoelectric element 1, a negative potential (−V) is applied to the drive electrodes (here, the first electrode 12 and the third electrode 20) during driving. As a result, the electric field Ef having the same direction as the direction P2 in which the spontaneous polarization is aligned (direction of the polarization) is applied to the second piezoelectric film 18 which is one piezoelectric film, and the electric field Er having the opposite direction to the electric field Ef applied to the second piezoelectric film 18 is applied to the first piezoelectric film 14 which is the other piezoelectric film.

It is preferable that the piezoelectric element 1 is configured such that the first electrode 12 and the third electrode 20 are connected. In a case where the first electrode 12 and the third electrode 20 are connected, drive control is easy.

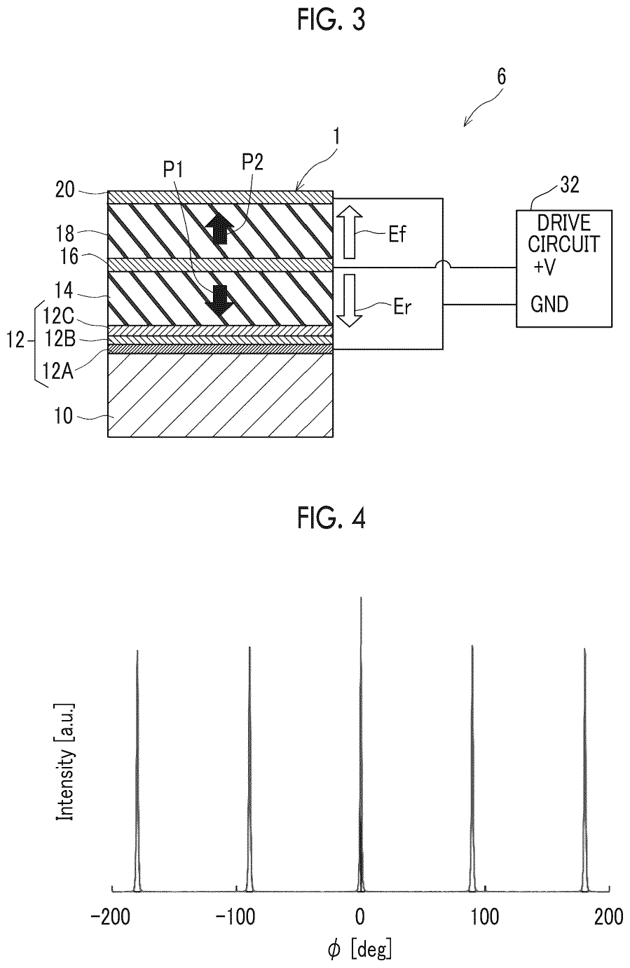

Meanwhile, as in an actuator 6 of a modification example shown in FIG. 3, a positive drive circuit that applies a positive potential to the drive electrode may be provided as a drive circuit 32. In the example shown in FIG. 3, the first electrode 12 and the third electrode 20 are connected to a ground terminal of the drive circuit 32, and the second electrode 16 is connected to a driving voltage output terminal of the drive circuit 32. That is, the first electrode 12 and the third electrode 20 are set to a ground potential, and the second electrode 16 functions as a drive electrode. In this case as well, by the drive circuit 32, the electric field Ef having the same direction as the direction P2 in which the spontaneous polarization is aligned (direction of the polarization) can be applied to the second piezoelectric film 18, and the electric field Er having an opposite direction to the electric field Ef applied to the second piezoelectric film 18 can be applied to the first piezoelectric film 14.

In the actuators 5 and 6 (refer to FIGS. 2 and 3), the electric field opposite to the electric field applied to the second piezoelectric film 18 is applied to the first piezoelectric film 14. Therefore, as shown in FIGS. 2 and 3, the first piezoelectric film 14 is polarized in a direction P1 opposite to the direction P2 of the polarization of the second piezoelectric film 18.

The actuators 5 and 6 comprise only a drive circuit having one polarity as the drive circuits 30 and 32, and can be realized at a low cost.

The present inventors have found that, as in a case of the piezoelectric element 1, with a configuration in which the first electrode 12, the first piezoelectric film 14, the second electrode 16, the second piezoelectric film 18, and the third electrode 20 are provided on the substrate 10 in this order, each of the first piezoelectric film 14 and the second piezoelectric film 18 has a perovskite-type oxide as a main component, one of the first piezoelectric film 14 and the second piezoelectric film 18 is an epitaxial film, and the other thereof is a uniaxial alignment film, responsiveness during the driving is good, and high long-term reliability is obtained (see Examples described below).

In the piezoelectric element, since the piezoelectric films are provided in a plurality of layers, a larger driving force can be obtained as compared with a piezoelectric element provided with a single layer of the piezoelectric film. In addition, as shown in FIG. 2 or FIG. 3, by setting the first electrode 12 and the third electrode 20 to the same potential and applying a voltage to generate electric fields between the first electrode 12 and the second electrode 16 and between the second electrode 16 and the third electrode 20, the drive circuit can be configured with one circuit. Therefore, it is possible to reduce the cost in adapting to the actuator, and it is possible to realize an actuator having a large driving force at a low cost.

### EXAMPLES

Hereinafter, specific examples and comparative examples of the piezoelectric element according to the present disclosure will be described. First, a configuration and a production method of the piezoelectric element of each example will be described.

As examples and comparative examples, piezoelectric elements each having a first electrode, a first piezoelectric film, a second electrode, a second piezoelectric film, and a third electrode in this order on a substrate (refer to FIG. 1) were produced. The layer configurations of Examples and Comparative Examples are collectively shown in Table 1 described later.

### Example 1

A production method of a piezoelectric element of Example 1 will be described.

Substrate with First Electrode

An electrode-attached substrate (SiZrO₂/Pt/SrRuO₃) comprising a first electrode layer in which a ZrO₂ film having a thickness of 40 nm, a Pt film having a thickness of 150 nm, and a SrRuO₃ film having a thickness of 60 nm were sequentially laminated on a substrate consisting of a silicon wafer was prepared.

### First Piezoelectric Film

As the first piezoelectric film, a Nb-added PZT film in which a Nb addition amount to the B site was 12 at % was formed on the first electrode. A film thickness of the Nb-added PZT film was set to 2 μm. Nb-added PZT was used as a target, and sputtering conditions were as follows. The Nb-added PZT target has a Pb composition ratio=1.3, a Zr/Ti molar ratio which is the MPB composition (Zr/Ti=52/48), that is, x=0.52, and a Nb composition ratio y=0.12. In Table 1, a case where the Nb composition ratio y=0.12, that is, a case where the Nb addition amount at the B site is 12%, is described as Nb-PZT as a default.

### Sputtering Conditions for First Piezoelectric Film

Distance between target and substrate: 100 mm
Target input power: 3 kW
Vacuum degree: 0.5 Pa, an Ar and O₂ mixed atmosphere (O₂ volume fraction: 2.5%)
Set temperature of substrate: 600° C.
Substrate bias voltage: +40 V

### Second Electrode

As the second electrode, IrOₓ (x≤2) of 50 nm and Ir of 200 nm were laminated on the first piezoelectric film in this order. The sputtering conditions were as follows.

### Sputtering Conditions for IrOₓ and Ir

Distance between target and substrate: 100 mm
Target input power: 200 W
Vacuum degree: 0.3 Pa, an Ar atmosphere during Ir film formation, an Ar and O₂ mixed atmosphere during IrOₓ film formation (O₂ volume fraction: 5%)
Set temperature of substrate: room temperature
After IrO₂ and Ir films were formed, the films were annealed at 350° C. for 15 minutes.

### Second Piezoelectric Film

As the second piezoelectric film, in the same manner as that of the first piezoelectric film, a Nb-added PZT film in which a Nb addition amount to the B site was 12 at % was formed on the second electrode. The target and the sputtering conditions were the same as those for the first piezoelectric film.

### Third Electrode

As the third electrode, IrOₓ of 50 nm and Ir of 100 nm were laminated on the second piezoelectric film in this order. The sputtering conditions were the same as those for the second electrode.

### Formation of Electrode Pattern for Evaluation

In order to form electrode pads for applying a voltage to the first electrode, the second electrode, and the third electrode, the third electrode, the second piezoelectric film, the second electrode, and the first piezoelectric film were patterned in this order by photolithography and dry etching.

A piezoelectric laminate of Example 1 was prepared by the above-described steps.

### Examples 2 to 8 and Comparative Examples 1 and 2

For Examples 2 to 8 and Comparative Examples 1 and 2, as the electrode-attached substrate, an electrode-attached substrate having a different configuration in the first electrode from the electrode-attached substrate of Example 1 was prepared. The configuration of the first electrode of each of Examples 2 to 8 and Comparative Examples 1 and 2 was as shown in Table 1. For example, in Example 2, a first electrode-attached substrate (Si/ZrO₂/Pt/BaRuO₃) in which the third film constituting the outermost surface of the first electrode in Example 1 was changed from SrRuO₃ to BaRuO₃ was prepared, and in Example 3, a first electrode-attached substrate (Si/HfO₂/Pt/SrRuO₃) in which the first film of the first electrode on the most substrate side in Example 1 was changed from ZrO₂ to HfO₂ was prepared.

For Comparative Example 1, an electrode-attached substrate (Si/SiO₂/ZrO₂/Pt/SrRuO₃) comprising a first electrode layer in which a ZrO₂ film having a thickness of 40 nm, a Pt film having a thickness of 150 nm, and a SrRuO₃ film having a thickness of 60 nm as in Example 1 were sequentially laminated on a substrate consisting of a silicon wafer with an oxidized film (SiO₂ film) was prepared. In Comparative Example 2, an electrode-attached substrate (Si/SiO₂/TiW/Ir) comprising a first electrode layer in which a TiW film having a thickness of 20 nm and an Ir film having a thickness of 150 nm were sequentially laminated on a substrate consisting of a silicon wafer with an oxidized film (SiO₂ film) was prepared.

The piezoelectric laminates of Examples 2 to 8 and Comparative Examples 1 and 2 were obtained by having the same configuration other than the first electrode-attached substrate as in Example 1.

In Examples 1 to 8, the first piezoelectric film was an epitaxial film (“epi” is written in the column of “alignment state” in Tables 1 and 2), and the second piezoelectric film was a uniaxial alignment film (“uniaxial alignment” is written in the column of “alignment state” in Tables 1 and 2). In addition, in Examples 1 to 8 in Table 1, the alignment state of the first electrode-attached substrate means the alignment state of the outermost surface of the first electrode. For example, in Example 1, SrRuO₃ as the outermost surface of the first electrode was an epitaxial film. In Comparative Examples 1 and 2, both the first piezoelectric film and the second piezoelectric film were uniaxial alignment films. In addition, SrRuO₃ of the outermost surface of the first electrode of Comparative Example 1 and Ir of the outermost surface of the first electrode of Comparative Example 2 were uniaxial alignment films. Examples 11 to 15 and Comparative Example 3

In Examples 11 to 15 and Comparative Example 3, the composition of the second electrode is different from that of Example 1. For example, the second electrode of Example 11 had a laminated structure (PtOₓ/Pt) in which PtOₓ and Pt were laminated in this order. In Example 14, a laminated structure (TaOₓ/Ta/Pt) in which TaOₓ, Ta, and Pt were laminated on the first piezoelectric film in this order was obtained.

In Examples 11 to 15, the first piezoelectric film was an epitaxial film, and the second piezoelectric film was a uniaxial alignment film. In Comparative Example 3, both the first piezoelectric film and the second piezoelectric film were epitaxial films.

### Examples 21 to 26

As shown in Table 2, in Examples 21 to 26, the combination of the compositions of the first piezoelectric film and the second piezoelectric film is different from that of Example 1. In Example 21, both the first piezoelectric film and the second piezoelectric film are PZT films in which the metal element M is not doped. In Example 21, the first piezoelectric film was a Nb 12%-added PZT film as in Example 1, and the second piezoelectric film was a Nb 10%-added PZT film. The first piezoelectric film and the second piezoelectric film of each of Examples 24 to 26 were as shown in Table 2.

In Examples 21 to 26, the first piezoelectric film was an epitaxial film, and the second piezoelectric film was a uniaxial alignment film. However, the epitaxial film of the first piezoelectric film of Example 26 was low in crystallinity as compared with other Examples. In addition, the uniaxial alignment films of the second piezoelectric films of Examples 25 and 26 were low in crystallinity as compared with the uniaxial alignment films of the second piezoelectric films of other Examples.

### Examples 31 to 35

In Examples 31 to 35, the compositions of the first piezoelectric film and the second piezoelectric film are different from those in Example 1. The first piezoelectric film and the second piezoelectric film of Example 31 were formed of a vanadium 1%-added PZT film. Similarly, in each of Examples 32 to 35, a PZT film to which 1% of Ta, Sb, Mo, and W were added was used.

In Examples 31 to 35, the first piezoelectric film was an epitaxial film, and the second piezoelectric film was a uniaxial alignment film.

### Crystallinity

The crystallinity of each of the first piezoelectric film and the second piezoelectric film was measured by observing a (111) peak of each piezoelectric film by φ scanning of X-ray diffraction (XRD). RINT3000 manufactured by Rigaku Corporation was used as a measuring device, and the measurement was performed under the following conditions.
Radiation source: CuKα
Optical system used: parallel optical system
X-ray incidence angle: set to an angle at which a (111) peak of the PZT-based perovskite-type oxide can be observed (θ=around 38 deg, χ=around 55 deg)
φ scanning condition: scan a range of −180 deg to 180 deg at 0.1 deg/step and 100 deg/min

In a case of an epitaxial film, four-fold symmetric peaks as shown in FIG. 4 were confirmed. In a case of a uniaxial alignment film, substantially straight line data of a specific intensity was acquired.

For each of Examples and Comparative Examples, the characteristics were evaluated.

### Preparation of Evaluation Sample

### Evaluation Sample

A strip-shaped portion of 2 mm×25 mm was cut out from the laminate to prepare a cantilever as an evaluation sample 1.

### Measurement of Piezoelectric Characteristics

A piezoelectric constant d₃₁ was measured for the evaluation of the piezoelectric characteristics for each of Examples and Comparative Examples.

The measurement of the piezoelectric constant d₃₁ was carried out using the evaluation sample. According to a method described in I. Kanno et al., Sensor and Actuator A 107 (2003) 68, the piezoelectric constant d₃₁ was measured. Specifically, the piezoelectric constant d₃₁ [pm/V] was measured by grounding the second electrode 16 and using a sinusoidal application voltage of +10 V±10 V, that is, a bias voltage of 10 V, and a sinusoidal application voltage having an amplitude of 10 V, with the first electrode 12 and the third electrode 20 as drive electrodes. The measurement results are shown in Tables 1 and 2. In Tables 1 and 2, evaluation results according to the following standards are also shown.
a: 360 pm/V or more
c: Less than 360 pm/V

### Measurement of Displacement Waveform

The displacement waveform is obtained by measuring a velocity waveform using an evaluation sample and integrating the velocity waveform. The second electrode was set to a ground potential, and the first electrode and the third electrode were used as drive electrodes to apply a drive signal (positive potential) of 200 Hz. The drive signal was a sine wave having an amplitude of 15 V. In this case, the velocity waveform of the evaluation sample was measured using an LV-1720A manufactured by Ono Sokki Co., Ltd.

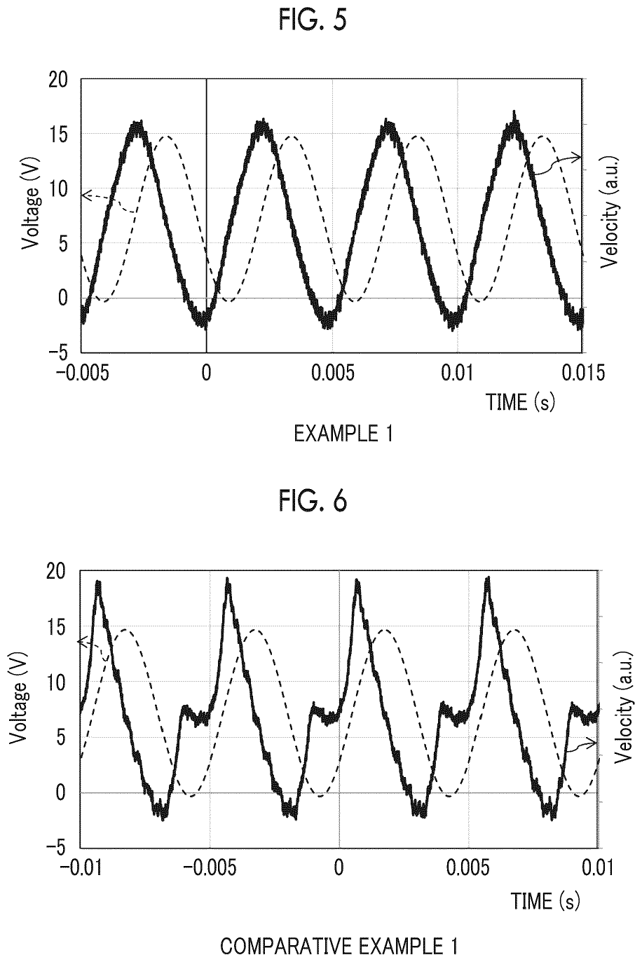

FIG. 5 shows a drive signal (broken line) and a velocity waveform (solid line) for Example 1. FIG. 6 shows a drive signal (broken line) and a velocity waveform (solid line) for Comparative Example 1. In FIGS. 5 and 6, the drive signal is shown in voltage, and the velocity waveform is shown in arbitrary units (a.u.). Since the displacement waveform is obtained by integrating the velocity waveform, in a case where the velocity waveform includes a nonlinear component, this means that the displacement waveform includes a nonlinear component.

The evaluation results according to the following standards are shown in Tables 1 and 2.
a: with nonlinear component
c: without nonlinear component

### Sheet Resistance Measurement of Second Electrode

A general high-precision flexible resistivity measuring system was used for the sheet resistance measurement. Specifically, VR250 manufactured by Kokusai Electric Semiconductor Service Inc. was used. The sheet resistance measurement was performed at 5 or 9 points in a plane of the second electrode, and the average value thereof was calculated. As a probe, a JS-TC-200-EP-200HK 4-terminal probe was used, with a needle diameter of 200 μmR, a needle spacing of 1 mm, a needle pressure of 200 g/piece, and a needle material of tungsten carbide.

For each example, a sheet resistance of the second electrode was evaluated as a, b, and c based on the following standards.
a: 1Ω or less
b: more than 1Ω and 10Ω or less
c: more than 10Ω

Tables 1 and 2 show a layer configuration and an evaluation result of each of Examples and Comparative Examples.

In addition, as an overall evaluation, regarding three evaluations of the piezoelectric characteristics, the displacement waveform, and the sheet resistance of the second electrode, a total value of the three evaluations is calculated as a: 2 points, b: 1 point, and c: 0 points, and the total value is shown in Table 1 and 2 as the overall evaluation.

TABLE 1

| | | First electrode-attached substrate | | First piezoelectric film | | Second | Second piezoelectric film | |
|---|---|---|---|---|---|---|---|---|
| | | | Alignment | | Alignment | electrode | | Alignment |
| | | Composition | state | Composition | state | Composition | Composition | state |
| Example | 1 | Si/ZrO₂/Pt/SrRuO₃ | epi | Nb—PZT | epi | IrOX/Ir | Nb—PZT | Uniaxial |
| | | | | | | | | alignment |
| Example | 2 | Si/ZrO₂/Pt/BaRuO₃ | epi | Nb—PZT | epi | IrOX/Ir | Nb—PZT | Uniaxial |
| | | | | | | | | alignment |
| Example | 3 | Si/HfO₂/Pt/SrRuO₃ | epi | Nb—PZT | epi | IrOX/Ir | Nb—PZT | Uniaxial |
| | | | | | | | | alignment |
| Example | 4 | Si/HfO₂/Pt/BaRuO₃ | epi | Nb—PZT | epi | IrOX/Ir | Nb—PZT | Uniaxial |
| | | | | | | | | alignment |
| Example | 5 | Si/ZrO₂/Ir/SrRuO₃ | epi | Nb—PZT | epi | IrOX/Ir | Nb—PZT | Uniaxial |
| | | | | | | | | alignment |
| Example | 6 | Si/ZrO₂/Ir/BaRuO₃ | epi | Nb—PZT | epi | IrOX/Ir | Nb—PZT | Uniaxial |
| | | | | | | | | alignment |
| Example | 7 | Si/HfO₂/Ir/SrRuO₃ | epi | Nb—PZT | epi | IrOX/Ir | Nb—PZT | Uniaxial |
| | | | | | | | | alignment |
| Example | 8 | Si/HfO₂/Ir/BaRuO₃ | epi | Nb—PZT | epi | IrOX/Ir | Nb—PZT | Uniaxial |
| | | | | | | | | alignment |
| Comparative | 1 | Si/SiO₂/ZrO₂/Pt/SrRuO₃ | Uniaxial | Nb—PZT | Uniaxial | IrOX/Ir | Nb—PZT | Uniaxial |
| Example | | | alignment | | alignment | | | alignment |
| Comparative | 2 | Si/SiO₂/TiW/Ir | Uniaxial | Nb—PZT | Uniaxial | IrOX/Ir | Nb—PZT | Uniaxial |
| Example | | | alignment | | alignment | | | alignment |
| Example | 11 | Si/ZrO₂/Pt/SrRuO₃ | epi | Nb—PZT | epi | PtOx/Pt | Nb—PZT | Uniaxial |
| | | | | | | | | alignment |
| Example | 12 | Si/ZrO₂/Pt/SrRuO₃ | epi | Nb—PZT | epi | RuOx/Ru | Nb—PZT | Uniaxial |
| | | | | | | | | alignment |
| Example | 13 | Si/ZrO₂/Pt/SrRuO₃ | epi | Nb—PZT | epi | ReOx/Re | Nb—PZT | Uniaxial |
| | | | | | | | | alignment |
| Example | 14 | Si/ZrO₂/Pt/SrRuO₃ | epi | Nb—PZT | epi | TaOx/Ta/Pt | Nb—PZT | Uniaxial |
| | | | | | | | | alignment |
| Example | 15 | Si/ZrO₂/Pt/SrRuO₃ | epi | Nb—PZT | epi | NiOx/Ni/Pt | Nb—PZT | Uniaxial |
| | | | | | | | | alignment |
| Comparative | 3 | Si/ZrO₂/Pt/SrRuO₃ | epi | Nb—PZT | epi | SrRu0₃ | Nb—PZT | epi |
| Example | | | | | | | | |

| | | | | Displacement waveform | | | |
|---|---|---|---|---|---|---|---|
| | | | | Nonlinear component | | Evaluation of | |
| | | Piezoelectric constant d₃₁ | | presence/ | | sheet resistance | Overall |
| | | (pm/V) | Evaluation | absence | Evaluation | of second electrode | evaluation |
| Example | 1 | 400 | a | Absent | a | a | 6 |
| Example | 2 | 390 | a | Absent | a | a | 6 |
| Example | 3 | 410 | a | Absent | a | a | 6 |
| Example | 4 | 395 | a | Absent | a | a | 6 |
| Example | 5 | 405 | a | Absent | a | a | 6 |
| Example | 6 | 385 | a | Absent | a | a | 6 |
| Example | 7 | 380 | a | Absent | a | a | 6 |
| Example | 8 | 380 | a | Absent | a | a | 6 |
| Comparative | 1 | 385 | a | Present | c | a | 4 |
| Example | | | | | | | |
| Comparative | 2 | 390 | a | Present | c | a | 4 |
| Example | | | | | | | |
| Example | 11 | 385 | a | Absent | a | a | 6 |
| Example | 12 | 385 | a | Absent | a | a | 6 |
| Example | 13 | 385 | a | Absent | a | a | 6 |
| Example | 14 | 380 | a | Absent | a | b | 5 |
| Example | 15 | 380 | a | Absent | a | b | 5 |
| Comparative | 3 | 370 | a | Absent | a | c | 4 |
| Example | | | | | | | |

TABLE 2

| | | First electrode-attached substrate | | | | Second | | |
|---|---|---|---|---|---|---|---|---|
| | | | Alignment | First piezoelectric film | | electrode | Second piezoelectric film | |
| | | Composition | state | Composition | Alignment state | Composition | Composition | Alignment state |
| Example | 21 | Si/ZrO₂/Pt/SrRuO₃ | epi | PZT | epi | IrOX/Ir | PZT | Uniaxial |
| | | | | | | | | alignment |
| Example | 22 | Si/ZrO₂/Pt/SrRuO₃ | epi | Nb1%—PZT | epi | IrOx/Ir | Nb1%—PZT | Uniaxial |
| | | | | | | | | alignment |
| Example | 23 | Si/ZrO₂/Pt/SrRuO₃ | epi | Nb12%—PZT | epi | IrOx/Ir | Nb10%—PZT | Uniaxial |
| | | | | | | | | alignment |
| Example | 24 | Si/ZrO₂/Pt/SrRuO₃ | epi | Nb25%—PZT | epi | IrOx/Ir | Nb25%—PZT | Uniaxial |
| | | | | | | | | alignment |
| Example | 25 | Si/ZrO₂/Pt/SrRuO₃ | epi | Nb30%—PZT | epi | IrOx/Ir | Nb30%—PZT | Uniaxial |
| | | | | | | | | alignment |
| | | | | | | | | Low crystallinity |
| Example | 26 | Si/ZrO₂/Pt/SrRuO₃ | epi | Nb35%—PZT | epi | IrOx/Ir | Nb35%—PZT | Uniaxial |
| | | | | | Low crystallinity | | | alignment |
| | | | | | | | | Low crystallinity |
| Example | 31 | Si/ZrO₂/Pt/SrRuO₃ | epi | V1%—PZT | epi | IrOx/Ir | V1%—PZT | Uniaxial |
| | | | | | | | | alignment |
| Example | 32 | Si/ZrO₂/Pt/SrRuO₃ | epi | Ta1%—PZT | epi | IrOx/Ir | Ta1%—PZT | Uniaxial |
| | | | | | | | | alignment |
| Example | 33 | Si/ZrO₂/Pt/SrRuO₃ | epi | Sb1%—PZT | epi | IrOx/Ir | Sb1%—PZT | Uniaxial |
| | | | | | | | | alignment |
| Example | 34 | Si/ZrO₂/Pt/SrRuO₃ | epi | Mo1%—PZT | epi | IrOx/Ir | Mo1%—PZT | Uniaxial |
| | | | | | | | | alignment |
| Example | 35 | Si/ZrO₂/Pt/SrRuO₃ | epi | W1%—PZT | epi | IrOx/Ir | W1%—PZT | Uniaxial |
| | | | | | | | | alignment |

| | | | | Displacement waveform | | | |
|---|---|---|---|---|---|---|---|
| | | | | Nonlinear component | | Evaluation of | |
| | | Piezoelectric constant d₃₁ | | presence/ | | sheet resistance | Overall |
| | | (pm/V) | Evaluation | absence | Evaluation | of second electrode | evaluation |
| Example | 21 | 360 | a | Absent | a | a | 6 |
| Example | 22 | 375 | a | Absent | a | a | 6 |
| Example | 23 | 390 | a | Absent | a | a | 6 |
| Example | 24 | 395 | a | Absent | a | a | 6 |
| Example | 25 | 380 | a | Absent | a | a | 6 |
| Example | 26 | 375 | a | Absent | a | a | 6 |
| Example | 31 | 375 | a | Absent | a | a | 6 |
| Example | 32 | 370 | a | Absent | a | a | 6 |
| Example | 33 | 390 | a | Absent | a | a | 6 |
| Example | 34 | 365 | a | Absent | a | a | 6 |
| Example | 35 | 370 | a | Absent | a | a | 6 |

In all of Examples in which the first piezoelectric film was an epitaxial film and the second piezoelectric film was a uniaxial alignment film, the overall evaluation was 5 points or more. In a case where the overall evaluation is 5 points or more, the piezoelectric characteristics are high (that is, a large driving force is obtained), the responsiveness is good, and the long-term reliability can be obtained. In a case where the overall evaluation is 6 points or more, it is considered that more excellent long-term reliability can be obtained. In Comparative Examples 1 and 2 in which both the first piezoelectric film and the second piezoelectric film are uniaxial alignment films, there was a nonlinear component in the displacement waveform, and the responsiveness was low. In Comparative Examples 1 and 2, both the first piezoelectric film and the second piezoelectric film are uniaxial alignment films. In this case, the directions of the spontaneous polarization of two layers of the piezoelectric films are the same. As in the present embodiment, in a case where electric fields in opposite directions are applied to the first piezoelectric film and the second piezoelectric film, an electric field in a direction opposite to the spontaneous polarization is applied to at least one piezoelectric film in Comparative Examples 1 and 2. Since it is necessary to reverse the direction of the spontaneous polarization, a delay occurs in the response, and as shown in FIG. 6, it is considered that a nonlinear component occurs in the displacement waveform indicated by a solid line with respect to a shape of a driving waveform indicated by a broken line. In a case where at least one layer is an epitaxial film as in Examples, since the spontaneous polarization of the epitaxial film is isotropic, by applying an electric field in a direction opposite to a uniaxial alignment film, the epitaxial film can be easily polarized in that direction, and a stable polarization state can be obtained. Therefore, it can be considered that the nonlinear component does not occur in the displacement waveform in a case where electric fields in opposite directions are applied to the first piezoelectric film and the second piezoelectric film.

In addition, in Comparative Example 3 in which both the first piezoelectric film and the second piezoelectric film were epitaxial films, there was no problem in responsiveness, but the sheet resistance of the second electrode was large. In a case where the sheet resistance is large, heat is generated by driving, and power consumption increases due to the heat. In addition, in a case where the sheet resistance is large, Pb is precipitated in the piezoelectric film at an interface with the piezoelectric film due to a temperature rise caused by the heat generation during long-term driving, which leads to a decrease in the withstand voltage and the durability and thus a decrease in the long-term reliability. In addition, in a case where both the first piezoelectric film and the second piezoelectric film are epitaxial films as in Comparative Example 3, it is presumed that a stress is large as compared with a case where at least one of the first piezoelectric film or the second piezoelectric film is a uniaxial alignment film. In a case of being driven for a long term, the higher the stress is, the more likely the occurrence of problems such as cracking and peeling is. Therefore, it is considered that the long-term reliability can be improved by using one layer of two layers of the piezoelectric films as an epitaxial film and the other layer as a uniaxial alignment film, as compared with a case where both of the two layers of the piezoelectric films are epitaxial films.

All documents, patent applications, and technical standards described in the present specification are incorporated in the present specification by reference to the same extent as in a case where each document, patent application, and technical standard are specifically and individually noted to be incorporated by reference.

Furthermore, the following appendices will be disclosed in relation to the above-described embodiment.

### Appendix 1

A piezoelectric element comprising:
a substrate; and
a first electrode, a first piezoelectric film, a second electrode, a second piezoelectric film, and a third electrode provided on the substrate in this order,
in which the first piezoelectric film and the second piezoelectric film each have a perovskite-type oxide as a main component, and
one of the first piezoelectric film and the second piezoelectric film is an epitaxial film and the other is a uniaxial alignment film.

### Appendix 2

The piezoelectric element according to Appendix 1, in which the first piezoelectric film is an epitaxial film and the second piezoelectric film is a uniaxial alignment film.

### Appendix 3

The piezoelectric element according to Appendix 2, in which a surface of the first electrode in contact with the first piezoelectric film is an epitaxial film.

### Appendix 4

The piezoelectric element according to any one of Appendices 1 to 3, in which the perovskite-type oxide which is a main component of the first piezoelectric film and the perovskite-type oxide which is a main component of the second piezoelectric film consist of the same constituent elements.

### Appendix 5

The piezoelectric element according to any one of Appendices 1 to 4, in which the perovskite-type oxide is lead zirconate titanate or lead zirconate titanate to which a metal element M is added, and the metal element M is at least one of vanadium, niobium, tantalum, antimony, molybdenum, or tungsten.

### Appendix 6

The piezoelectric element according to Appendix 5, in which the metal element M in the perovskite-type oxide is niobium, and in a composition ratio of the perovskite-type oxide included in each of the first piezoelectric film and the second piezoelectric film, an addition amount of at least the metal element M is the same.

### Appendix 7

The piezoelectric element according to any one of Appendices 1 to 6, in which the first electrode, the second electrode, and the third electrode each contain at least one of iridium, platinum, strontium ruthenate, barium ruthenate, zirconium oxide, hafnium oxide, ruthenium, ruthenium oxide, iridium oxide, platinum oxide, or rhenium oxide.

### Appendix 8

The piezoelectric element according to any one of Appendices 1 to 7, in which the first electrode and the third electrode are maintained at a ground potential, and the second electrode is a drive electrode for applying a positive driving voltage to the first piezoelectric film and the second piezoelectric film.

### Appendix 9

The piezoelectric element according to any one of Appendices 1 to 7, in which the second electrode is maintained at a ground potential, and the first electrode and the third electrode are drive electrodes for applying a negative driving voltage to the first piezoelectric film and the second piezoelectric film.

### Appendix 10

An actuator comprising:
the piezoelectric element according to any one of Appendices 1 to 9; and
a drive circuit that applies a driving voltage to the piezoelectric element,
in which the drive circuit applies, to the other piezoelectric film which is the uniaxial alignment film, an electric field having the same direction as a direction of self-poling which is polarization that the other piezoelectric film spontaneously has immediately after film formation, and applies, to the one piezoelectric film which is the epitaxial film, an electric field having a direction opposite to the electric field applied to the other piezoelectric film.

What is claimed is:

1. A piezoelectric element comprising:
a substrate; and
a first electrode, a first piezoelectric film, a second electrode, a second piezoelectric film, and a third electrode provided on the substrate in this order,
wherein the first piezoelectric film and the second piezoelectric film each have a perovskite-type oxide as a main component, and
one of the first piezoelectric film and the second piezoelectric film is an epitaxial film and the other is a uniaxial alignment film.

2. The piezoelectric element according to claim 1,
wherein the first piezoelectric film is the epitaxial film, and the second piezoelectric film is the uniaxial alignment film.

3. The piezoelectric element according to claim 2,
wherein a surface of the first electrode in contact with the first piezoelectric film is an epitaxial film.

4. The piezoelectric element according to claim 1,
wherein the perovskite-type oxide which is a main component of the first piezoelectric film and the perovskite-type oxide which is a main component of the second piezoelectric film consist of the same constituent elements.

5. The piezoelectric element according to claim 3,
wherein the perovskite-type oxide is lead zirconate titanate or lead zirconate titanate to which a metal element M is added, and
the metal element M is at least one of vanadium, niobium, tantalum, antimony, molybdenum, or tungsten.

6. The piezoelectric element according to claim 5,
wherein the metal element M in the perovskite-type oxide is niobium, and
in a composition ratio of the perovskite-type oxide included in each of the first piezoelectric film and the second piezoelectric film, an addition amount of at least the metal element M is the same.

7. The piezoelectric element according to claim 1,
wherein the first electrode, the second electrode, and the third electrode each contain at least one of iridium, platinum, strontium ruthenate, barium ruthenate, zirconium oxide, hafnium oxide, ruthenium, ruthenium oxide, iridium oxide, platinum oxide, or rhenium oxide.

8. The piezoelectric element according to claim 1,
wherein the first electrode and the third electrode are maintained at a ground potential, and the second electrode is a drive electrode for applying a positive driving voltage to the first piezoelectric film and the second piezoelectric film.

9. The piezoelectric element according to claim 1,
wherein the second electrode is maintained at a ground potential, and the first electrode and the third electrode are drive electrodes for applying a negative driving voltage to the first piezoelectric film and the second piezoelectric film.

10. An actuator comprising:
the piezoelectric element according to claim 1; and
a drive circuit that applies a driving voltage to the piezoelectric element,
wherein the drive circuit applies, to the other piezoelectric film which is the uniaxial alignment film, an electric field having the same direction as a direction of self-poling which is polarization that the other piezoelectric film spontaneously has immediately after film formation, and applies, to the one piezoelectric film which is the epitaxial film, an electric field having a direction opposite to the electric field applied to the other piezoelectric film.
